(19) United States
(12) Patent Application Publication
(10) Pub. No.: US 2026/0177319 A1
(43) Pub. Date: Jun. 25, 2026

(54) VACUUM PIPE ASSEMBLY, SUPPORT UNIT, AND SUBSTRATE TREATING APPARATUS

(71) Applicant: SEMES CO., LTD., Cheonan-si (KR)

(72) Inventor: Kyung Sik SHIN, Asan-si (KR)

(21) Appl. No.: 19/390,906

(22) Filed: Nov. 17, 2025

(30) Foreign Application Priority Data
Dec. 20, 2024 (KR) 10-2024-0192766

(51) Int. Cl. F27D 5/00; F27B 17/00; H10P 72/76

(52) U.S. Cl. CPC F27D 5/0037; F27B 17/0025; H10P 72/7614

(57) ABSTRACT

The present disclosure provides a vacuum pipe assembly, a support unit, and a substrate treating apparatus. A vacuum pipe assembly according to an embodiment of the present disclosure includes a vacuum pipe disposed through a through-hole of a heater cup, and connected to a vacuum hole of a heating plate disposed above the heater cup; and a spring member installed in the heater cup, and elastically supporting the vacuum pipe toward the heating plate, wherein the vacuum pipe is installed in a floating structure, which is not fixed to the heater cup by the spring member.

### CROSS-REFERENCE TO RELATED APPLICATION(S)

This application claims the benefit of priority to Korean Patent Application No. 10-2024-0192766 filed on December 20, 2024 in the Korean Intellectual Property Office, the entire disclosure of which is incorporated herein by reference for all purposes.

### BACKGROUND

The present disclosure relates to a vacuum pipe assembly, a support unit, and a substrate treating apparatus.

To manufacture semiconductor devices, various processes such as photolithography, etching, deposition, ion implantation, cleaning, and the like, are performed. Thereamong, the photo process is a process for forming patterns and plays an important role in achieving high integration of semiconductor devices.

The photo process is largely comprised of a coating process, an exposure process, and a development process, and a baking process is performed before and after the exposure process.

The baking process is a process of heat treating a substrate, in which the substrate is disposed on a heating plate and heat treated.

Meanwhile, in the case of a thick heating plate, a vacuum passage is formed inside the heating plate, whereas in the case of a thin heating plate, it is difficult to form a vacuum passage inside the heating plate.

Accordingly, a connection pipe is used as an external vacuum passage of the heating plate, and the connection pipe has a structure fixed to a heater cup.

During a high-temperature baking process, the heater cup has a different thermal expansion displacement from the heating plate, and the connection pipe fixed to the heater cup has a limitation that leakage may occur between the connection pipe and the heating plate.

In addition, since the connection pipe includes a rubber portion, there is a problem that the rubber portion of the connection pipe deteriorates during the high-temperature baking process.

### SUMMARY

The present disclosure has been created to solve the above-described problems, and an aspect of the present disclosure is to provide a vacuum pipe assembly, a support unit, and a substrate treating apparatus configured not to deteriorate as an external vacuum passage of a heating plate.

In order to achieve the object, according to an aspect of the present disclosure, a vacuum pipe assembly includes a vacuum pipe disposed through a through-hole of a heater cup, and connected to a vacuum hole of a heating plate disposed above the heater cup; and a spring member installed in the heater cup, and elastically supporting the vacuum pipe toward the heating plate, wherein the vacuum pipe is installed in a floating structure, which is not fixed to the heater cup by the spring member.

The spring member is a coil spring and through which the vacuum pipe may penetrate.

A side jaw may be formed on a side portion of the vacuum pipe, a lower end portion of the spring member may be supported on a bracket formed on a periphery of the through-hole of the heater cup, and an upper end portion of the spring member may elastically press the side jaw upwardly.

An upper end portion of the vacuum pipe may be inserted into the vacuum hole of the heating plate, and may be formed of a material having a higher coefficient of thermal expansion than the heating plate.

The heating plate may be formed of ceramic, and the vacuum pipe may be formed of metal.

In order to seal a connection between the vacuum hole of the heating plate and the vacuum pipe, the vacuum pipe may have a sealing jaw formed along the side portion in the upper end portion to contact a lower edge of the vacuum hole.

According to another aspect of the present disclosure, a support unit may be provided, the support unit including a heating plate; a heater cup supporting the heating plate; and a vacuum pipe assembly installed through the heating plate and the heater cup, wherein the vacuum pipe assembly includes a vacuum pipe disposed through a through-hole of the heater cup, and connected to a vacuum hole of a heating plate disposed above the heater cup; and a spring member installed in the heater cup, and elastically supporting the vacuum pipe toward the heating plate, wherein the vacuum pipe is installed in a floating structure, which is not fixed to the heater cup by the spring member.

According to another aspect of the present disclosure, a substrate treating apparatus may be provided, the substrate treating apparatus including a process chamber having a processing space for a substrate formed therein; and a support unit disposed in the processing space, and supporting and heating the substrate, wherein the support unit includes a heating plate; a heater cup supporting the heating plate; and a vacuum pipe assembly installed through the heating plate and the heater cup, wherein the vacuum pipe assembly includes a vacuum pipe disposed through a through-hole of the heater cup, and connected to a vacuum hole of a heating plate disposed above the heater cup; and a spring member installed in the heater cup, and elastically supporting the vacuum pipe toward the heating plate, wherein the vacuum pipe is installed in a floating structure, which is not fixed to the heater cup by the spring member.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic perspective view illustrating a support unit according to an embodiment of the present disclosure;

FIG. 2 is another schematic perspective view illustrating a support unit according to an embodiment of the present disclosure;

FIG. 3 is a cross-sectional view illustrating the support unit of FIGS. 1 and 2;

FIG. 4 is an enlarged view illustrating A of FIG. 3; and

FIG. 5 is an enlarged view illustrating B of FIG. 3.

### DETAILED DESCRIPTION

Hereinafter, preferred embodiments of the present disclosure will be described in detail so that those skilled in the art could easily practice the present disclosure with reference to the accompanying drawings. However, in describing a preferred embodiment of the present disclosure in detail, if it is determined that a detailed description of a related known function or configuration may unnecessarily obscure the subject matter of the present disclosure, the detailed description will be omitted. In addition, the same reference numerals are used throughout the drawings for parts having similar functions and actions. In addition, in the present specification, terms such as ‘upper,’ ‘upper portion,’ ‘upper surface,’ ‘lower,’ ‘lower portion,’ ‘lower surface,’ ‘side surface,’ and the like are based on the drawings, and in practice, it may be different depending on a direction in which the components are disposed.

In addition, throughout the specification, when a part is said to be ‘connected’ to another part, this is not only when it is ‘directly connected,’ but also when it is ‘indirectly connected’ with other components therebetween. In addition, ‘including’ a certain component means that other components may be further included without excluding other components unless otherwise stated.

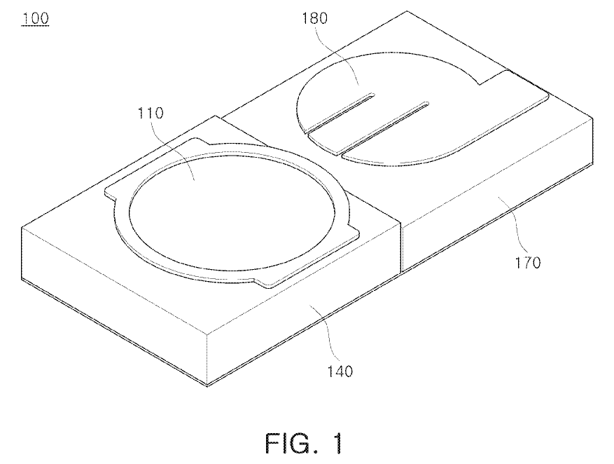

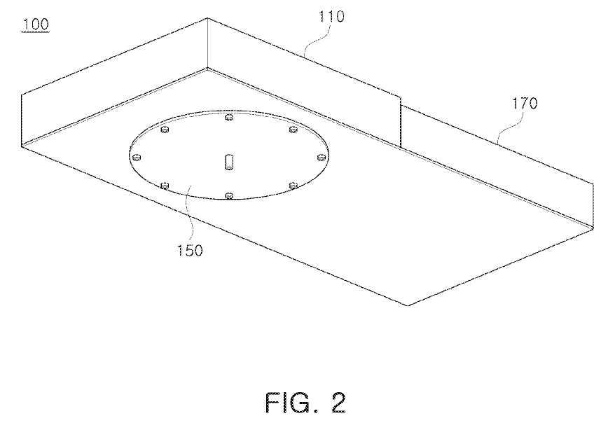

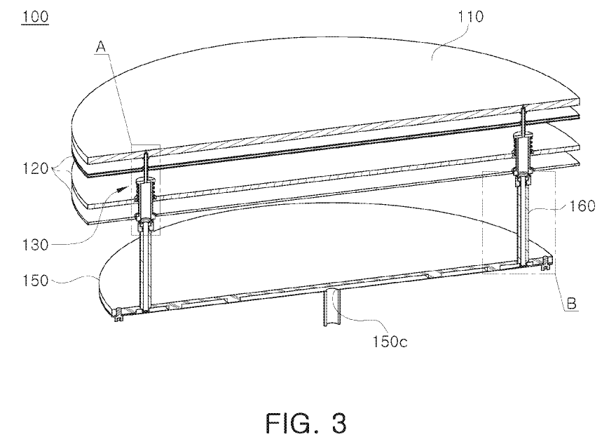

FIG. 1 is a schematic perspective view illustrating a support unit according to an embodiment of the present disclosure, FIG. 2 is another schematic perspective view illustrating a support unit according to an embodiment of the present disclosure, and FIG. 3 is a cross-sectional view illustrating the support unit of FIGS. 1 and 2.

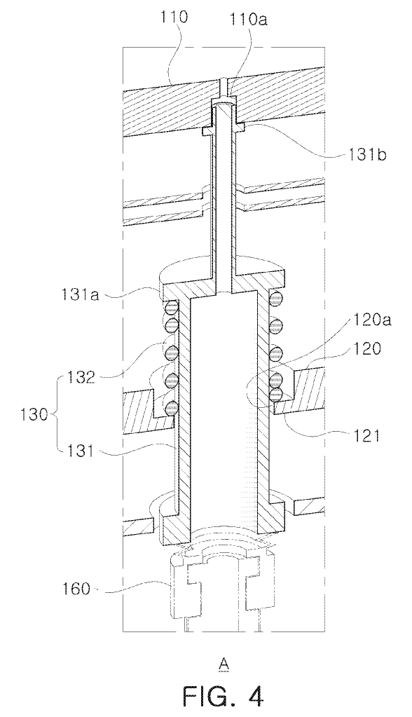

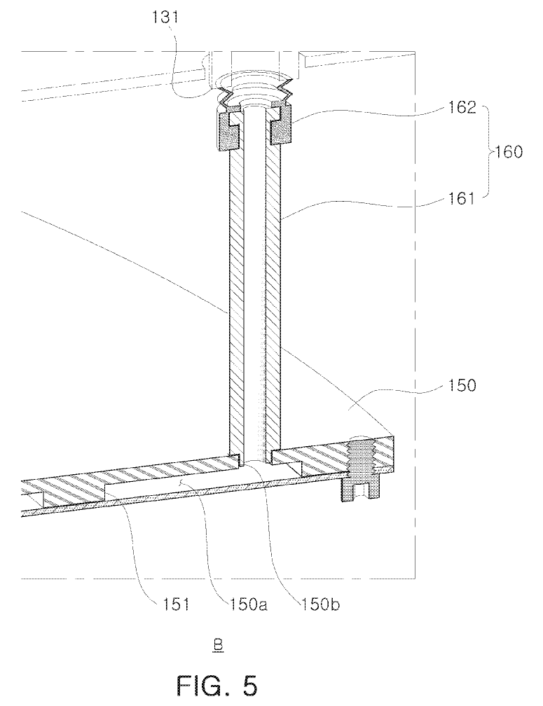

In addition, FIG. 4 is an enlarged view illustrating A of FIG. 3, and FIG. 5 is an enlarged view illustrating B of FIG. 3.

Referring to the drawing, a substrate treating apparatus according to an embodiment of the present disclosure includes a process chamber and a support unit 100.

Although not shown in the drawings, the process chamber is configured so that a substrate is processed therein. To this end, the process chamber has a processing space in which the substrate is processed.

Such a process chamber may be, for example, a bake chamber, and in the photo process, the bake chamber is used for baking the substrate at high temperatures.

In addition, the support unit 100 is disposed in the processing space of the process chamber to support the substrate.

The support unit 100 supports the substrate firmly and stably, and may be configured with a lifting pin (not shown) used when receiving or transferring the substrate.

The support unit 100 supports the substrate firmly and stably, and may be configured with a lifting pin (not shown) used when receiving or transferring the substrate.

Specifically, the support unit 100 may include a heating plate 110, a heater cup 120, and a vacuum pipe assembly 130.

The heating plate 110 is a portion on which the substrate is disposed, and has a heating wire disposed therein to heat the substrate.

In addition, the heater cup 120 fixes a position thereof while supporting the heating plate 110. To this end, the heater cup 120 may have the shape such as a cup, as an example, and the heater cup 120 may be configured to support the heating plate 110 firmly and stably, but is not limited by the present disclosure in terms of the specific structure.

Meanwhile, the vacuum pipe assembly 130 is installed through the heating plate 110 and the heater cup 120.

The vacuum pipe assembly 130 may include a vacuum pipe 131 and a spring member 132.

The vacuum pipe 131 is a pipe connected to a vacuum pump (not shown), and vacuum pressure is generated thereinside when the vacuum pump operates.

The vacuum pipe 131 is disposed through a through-hole 120a of the heater cup 120, and may have a structure connected to a vacuum hole 110a of a heating plate 110 disposed above the heater cup 120. Due thereto, when the substrate is disposed on the heating plate 110, the substrate may be vacuum-suctioned into the vacuum hole 110a of the heating plate 110.

The vacuum pipe 131 configured in this manner does not have a rubber pad in a portion, in contact with the heating plate 110, so the vacuum pipe 131 is not deteriorated even due to the high heat of the baking process.

An upper end portion of the vacuum pipe 131 may be inserted into the vacuum hole 110a of the heating plate 110 to be connected to the vacuum hole 110a of the heating plate 110.

The vacuum pipe 131 may be formed of a material having a higher coefficient of thermal expansion than the heating plate 110.

As an example, the heating plate 110 may be formed of ceramic, and the vacuum pipe 131 may be formed of metal.

During the baking process, the heating plate 110 and vacuum pipe 131 may thermally expand due to high temperature, and the vacuum pipe 131 thermally expands more than the heating plate 110.

Due thereto, the upper end portion of the vacuum pipe 131 may be in close contact with the vacuum hole 110a of the heating plate 110 and be tightly fitted thereinto, thereby reliably blocking air from flowing into the interior of the vacuum pipe 131 from the exterior of the vacuum pipe 131.

In addition thereto, the vacuum pipe 131 may have a sealing jaw 131b.

The sealing jaw 131b may be formed along the side portion in the upper end portion of the vacuum pipe 131 to have a structure contacting a lower edge of the vacuum hole 110a.

The sealing jaw 131b may seal the connection between the vacuum hole 110a of the heating plate 110 and the vacuum pipe 131.

That is, the sealing jaw 131b of the vacuum pipe 131 may minimize or block air from flowing upwardly through the vacuum hole 110a and the vacuum pipe 131 by increasing the resistance of the air flow.

Meanwhile, the spring member 132 is installed in the heater cup 120, and elastically supports the vacuum pipe 131 toward the heating plate 110.

By the spring member 132, the vacuum pipe 131 may be installed in a floating structure, which is not fixed to the heater cup 120.

As an example, the spring member 132 is a coil spring and may have a structure through which the vacuum pipe 131 penetrates.

In addition, the spring member 132 may have a structure in which a lower end portion of the spring member 132 is supported on a bracket 121 formed on a periphery of the through-hole 120a of the heater cup 120. In addition, a side jaw 131a may be formed on a side portion of the vacuum pipe 131, and the spring member 132 may have a structure in which an upper end portion thereof elastically presses the side jaw 131a upwardly.

That is, the spring member 132 may be installed in the heater cup 120 and elastically supports the vacuum pipe 131 toward the heating plate 110, so that the vacuum pipe 131 may be installed in a floating structure, which is not fixed to the heater cup 120.

The floating structure of the vacuum pipe 131 implemented by the spring member 132 is a structure which allows the vacuum pipe 131 to be separated from the heater cup 120 without being connected and fixed thereto.

That is, the floating structure by the spring member 132 is a structure in which the vacuum pipe 131 is supported by the heater cup 120 but is not installed and fixed to the heater cup 120, and can absorb a thermal expansion displacement of the heater cup 120.

Since the heating plate 110 is formed of ceramic and the heater cup 120 is formed of metal, the heating plate 110 and the heater cup 120 have different coefficients of thermal expansion.

Due thereto, the heating plate 110 and the heater cup 120 may thermally expand due to the high temperature during the baking process, and the heater cup 120 thermally expands more than the heating plate 110.

However, since the vacuum pipe 131 is not fixed to the heater cup 120 but is installed in a floating structure by a spring member 132, even if the heating plate 110 and the heater cup 120 thermally expand more than the heating plate 110, the connection of the heating plate 110 with the vacuum hole 110a may be stably maintained while being supported by the heater cup 120.

Meanwhile, the support unit 100 may further include a heating frame box 140, a fume trap plate 150, and an extension pipe 160.

The heating frame box 140 may have a housing structure in which upper and lower portions thereof are open.

As illustrated in FIG. 1, the heating frame box 140 may have a heating plate 110 disposed on the open upper portion, and a heater cup 120 disposed therein. For reference, a chill frame box 170 equipped with a chill plate 180 may be disposed next to the heating frame box 140.

In addition, the fume trap plate 150 may be disposed below the heater cup 120, as illustrated in FIG. 2.

The fume trap plate 150 serves to remove fumes contained in air suctioned through a vacuum pipe 131 from a vacuum hole 110a of a heating plate 110.

The fume trap plate 150 may have a structure which is detachably attached from the open lower portion of the heating frame box 140.

The extension pipe 160 connects the vacuum pipe 131 and the fume trap plate 150.

Conventionally, the fume trap plate was installed inside the chill frame box in which the chill plate was installed. However, in such cases, a distance from the vacuum hole of the heating plate to the fume trap plate of the chill frame box is long, so fumes may accumulate in the long air movement path therebetween. In addition, as the fume trap plate is installed inside the chill frame box, the chill frame box should be disassembled for maintenance, which has limitations in efficiency in terms of time and labor load.

However, in the present disclosure, since the fume trap plate 150 is installed in the heating frame box 140, rather than the chill frame box 170, a distance from the vacuum hole 110a of the heating plate 110 to the fume trap plate 150 is short), so that fumes may be removed from an initial portion of an air movement path. In addition, since the fume trap plate 150 has a structure detachably attached to the open lower portion of the heating frame box 140, the fume trap plate 150 may be easily disassembled from the outside of the heating frame box 140 during maintenance, which is efficient in terms of time and labor load.

Specifically, as illustrated in FIGS. 3 and 5, the fume trap plate 150 may have a vacuum passage 150a formed therein, a suction hole 150b formed in the upper portion communicating with the vacuum passage 150a, and an exhaust hole 150c formed in the lower portion communicating with the vacuum passage 150a. In addition, a plurality of heat dissipation members 151 may be formed inside the vacuum passage 150a.

The fume trap plate 150 configured in this manner may lower the temperature by the heat dissipation member 151 when the high-temperature air suctioned in from the vacuum hole 110a of the heating plate 110 flows.

The extension pipe 160 may connect the vacuum pipe 131 and the fume trap plate 150, so that air suctioned through the vacuum pipe 131 from the vacuum hole 110a of the heating plate 110 may flow to the fume trap plate 150.

Such an extension pipe 160 may include a pipe body 161 and an elastic pad 162 as shown in FIG. 5.

A lower end portion of the pipe body 161 may be inserted and assembled into the suction hole 150b of the fume trap plate 150.

In addition, the elastic pad 162 may be formed on an upper end portion of the pipe body 161, and may be formed of a rubber material to be connected to a lower surface of the vacuum pipe 131 in a sealed manner.

As described above, the elastic pad 162 is formed of a rubber material, and may provide elasticity due to a material thereof, and furthermore, as illustrated in the drawings, the elastic pad 162 may have a structure in which the upper portion is folded to provide elasticity due to a structure thereof.

As a result, as the elastic pad 162 is elastically pressed against a lower surface of the vacuum pipe 131, and is in contact therewith, the extension pipe 160 may be connected to the vacuum pipe 131 in a sealed manner.

According to an embodiment of the present disclosure, a vacuum pipe assembly, a support unit, and a substrate treating apparatus do not have a rubber pad on a vacuum pipe, so that a vacuum pipe may not deteriorate at high temperatures, and the vacuum pipe is installed in a heater cup in a floating structure, which is not fixed to a heater cup, so that the connection between the vacuum pipe and a vacuum hole of the heating plate may be stably maintained even with different thermal expansions of the heating plate and the heater cup.

While exemplary embodiments have been shown and described above, it will be apparent to those skilled in the art that modifications and variations could be made without departing from the scope of the present invention as defined by the appended claims.

What is claimed is:

1. A vacuum pipe assembly, comprising:
a vacuum pipe disposed through a through-hole of a heater cup, and connected to a vacuum hole of a heating plate disposed above the heater cup; and
a spring member installed in the heater cup, and elastically supporting the vacuum pipe toward the heating plate,
wherein the vacuum pipe is installed in a floating structure, which is not fixed to the heater cup by the spring member.

2. The vacuum pipe assembly of claim 1, wherein the spring member is a coil spring and through which the vacuum pipe penetrates.

3. The vacuum pipe assembly of claim 1, wherein a side jaw is formed on a side portion of the vacuum pipe, and
a lower end portion of the spring member is supported on a bracket formed on a periphery of the through-hole of the heater cup, and an upper end portion of the spring member elastically presses the side jaw upwardly.

4. The vacuum pipe assembly of claim 1, wherein an upper end portion of the vacuum pipe is inserted into the vacuum hole of the heating plate, and is formed of a material having a higher coefficient of thermal expansion than the heating plate.

5. The vacuum pipe assembly of claim 4, wherein the heating plate is formed of ceramic, and the vacuum pipe is formed of metal.

6. The vacuum pipe assembly of claim 4, wherein, to seal a connection between the vacuum hole of the heating plate and the vacuum pipe, the vacuum pipe has a sealing jaw formed along a side portion in the upper end portion to contact a lower edge of the vacuum hole.

7. A support unit, comprising:
a heating plate;
a heater cup supporting the heating plate; and
a vacuum pipe assembly installed through the heating plate and the heater cup,
wherein the vacuum pipe assembly includes
a vacuum pipe disposed through a through-hole of the heater cup, and connected to a vacuum hole of a heating plate disposed above the heater cup; and
a spring member installed in the heater cup, and elastically supporting the vacuum pipe toward the heating plate,
wherein the vacuum pipe is installed in a floating structure, which is not fixed to the heater cup by the spring member.

8. The support unit of claim 7, wherein the spring member is a coil spring and through which the vacuum pipe penetrates.

9. The support unit of claim 7, wherein a side jaw is formed on a side portion of the vacuum pipe, and
a lower end portion of the spring member is supported on a bracket formed on a periphery of the through-hole of the heater cup, and an upper end portion of the spring member elastically presses the side jaw upwardly.

10. The support unit of claim 7, wherein an upper end portion of the vacuum pipe is inserted into the vacuum hole of the heating plate, and is formed of a material having a higher coefficient of thermal expansion than the heating plate.

11. The support unit of claim 10, wherein the heating plate is formed of ceramic, and the vacuum pipe is formed of metal.

12. The support unit of claim 10, wherein, to seal a connection between the vacuum hole of the heating plate and the vacuum pipe, the vacuum pipe has a sealing jaw formed along a side portion in the upper end portion to contact a lower edge of the vacuum hole.

13. A substrate treating apparatus, comprising:
a process chamber having a processing space for a substrate formed therein; and
a support unit disposed in the processing space, and supporting and heating the substrate,
wherein the support unit includes
a heating plate;
a heater cup supporting the heating plate; and
a vacuum pipe assembly installed through the heating plate and the heater cup,
wherein the vacuum pipe assembly includes
a vacuum pipe disposed through a through-hole of the heater cup, and connected to a vacuum hole of a heating plate disposed above the heater cup; and
a spring member installed in the heater cup, and elastically supporting the vacuum pipe toward the heating plate,
wherein the vacuum pipe is installed in a floating structure, which is not fixed to the heater cup by the spring member.

14. The substrate treating apparatus of claim 13, wherein the spring member is a coil spring and through which the vacuum pipe penetrates.

15. The substrate treating apparatus of claim 13, wherein a side jaw is formed on a side portion of the vacuum pipe, and
a lower end portion of the spring member is supported on a bracket formed on a periphery of the through-hole of the heater cup, and an upper end portion of the spring member elastically presses the side jaw upwardly.

16. The substrate treating apparatus of claim 13, wherein an upper end portion of the vacuum pipe is inserted into the vacuum hole of the heating plate, and is formed of a material having a higher coefficient of thermal expansion than the heating plate.

17. The substrate treating apparatus of claim 16, wherein the heating plate is formed of ceramic, and the vacuum pipe is formed of metal.

18. The substrate treating apparatus of claim 16, wherein, to seal a connection between the vacuum hole of the heating plate and the vacuum pipe, the vacuum pipe has a sealing jaw formed along a side portion in the upper end portion to contact a lower edge of the vacuum hole.

19. The substrate treating apparatus of claim 13, wherein the support unit further comprises
a heating frame box having a housing structure in which upper and lower portions thereof are open, the heating plate is disposed in the open upper portion, and the heater cup is disposed therein;
a fume trap plate disposed below the heater cup, and detachably attached to the open lower portion of the heating frame box; and
an extension pipe connecting the vacuum pipe and the fume trap plate.

20. The substrate treating apparatus of claim 19, wherein the fume trap plate has a vacuum passage formed therein, has a suction hole communicating with the vacuum passage formed thereabove, has an exhaust hole communicating with the vacuum passage formed therebelow, and has a plurality of heat dissipation members formed inside the vacuum passage,
wherein the extension pipe includes
a pipe body of which a lower end portion is inserted and assembled into the suction hole of the fume trap plate; and
an elastic pad formed on an upper end portion of the pipe body, and formed of rubber to be connected to the lower end portion of the vacuum pipe in a sealed manner.
